(19) United States
(12) Patent Application Publication
(10) Pub. No.: US 2026/0251679 A1
(43) Pub. Date: Aug. 27, 2026

(54) PROBE PIN AND MANUFACTURING METHOD THEREFOR

(71) Applicant: PT&K CO., LTD., Anyang-si (KR)

(72) Inventors: Tae Yoon KIM, Gunpo-si (KR); Sung Chul KIM, Gunpo-si (KR)

(21) Appl. No.: 19/649,172

(22) Filed: Apr. 16, 2026

Related U.S. Application Data
(63) Continuation of application No. PCT/KR2024/015661, filed on Oct. 16, 2024.

(30) Foreign Application Priority Data
Oct. 18, 2023 (KR) 10-2023-0139461
Jul. 25, 2024 (KR) 10-2024-0098375

(51) Int. Cl. G01R 1/067; G01R 3/00

(52) U.S. Cl. CPC G01R 1/06755; G01R 3/00

(57) ABSTRACT

Provided is a probe pin used in a semiconductor inspection apparatus for inspecting a semiconductor chip by receiving an electrical signal from a tester, and the probe pin includes: a connection part electrically connected to the tester; a tension part having one end connected to the connection part and configured to be subjected to tension when the probe pin comes into contact with the semiconductor chip; and a contact part having one end connected to the other end of the tension part and the other end configured to come into contact with the semiconductor chip. The connection part and the contact part have rectangular cross-sections with rounded corners, and the tension part extends in a longitudinal direction, is recessed in a width direction, and is curved in one direction or both directions.

### DESCRIPTION

### CROSS REFERENCE TO RELATED APPLICATION(S)

This application is a continuation application of PCT/KR2024/015661, filed on October 16, 2024, which claims the benefits of priority to Korean Patent Application No. 10-2023-0139461, filed on October 18, 2023, and Korean Patent Application No. 10-2024-0098375, filed on July 25, 2024, the disclosures of which are herein incorporated by reference in their entirety.

### TECHNICAL FIELD

The present disclosure relates to a probe pin and a manufacturing method therefor.

### BACKGROUND

Unless otherwise indicated herein, the descriptions set forth in this section are not a prior art to claims of the present disclosure, and the inclusion in this section should not be considered a prior art.

A semiconductor fabrication process includes a front-end process of forming a plurality of semiconductor dies on a wafer and a back-end process of fabricating a semiconductor package by connecting wiring to each of the semiconductor dies.

In general, an EDS (Electrical Die Sorting) process is performed to test electrical characteristics of each semiconductor die constituting a wafer.

Specifically, the EDS process is performed by bringing a probe provided on a probe card into contact with a contact pad of a semiconductor die, transmitting an electrical signal from separate semiconductor inspection equipment through the probe, and reading the electrical signal output therefrom.

Recently, due to the miniaturization of semiconductors, a fine pitch is required not only at the wafer level but also at the semiconductor package level. Further, as the pads on semiconductor package are being smaller, there is a need to miniaturize a probe tip portion of a socket used to inspect the semiconductor package (semiconductor chip).

Such a semiconductor package is inspected using probe pins that come into contact with the pads on the semiconductor package. Recently, MEMS (Micro Electro Mechanical System) probe pins fabricated via a MEMS process have been widely used.

A MEMS probe pin is fabricated via a semiconductor fabrication process, such as a photolithography process, a plating process, and the like.

Furthermore, during the development or production of electronic products, the performance of the electronic product is evaluated by measuring the operating states of various electrical components mounted on a printed circuit board (PCB), such as the current or voltage flowing through the electrical components. Probe pins are used to perform such electrical inspection tests on the PCB. Probe pins for PCB inspection are also becoming increasingly miniaturized, and are commonly fabricated via the MEMS process.

However, the probe pins fabricated via the MEMS process are not produced by mechanically machining raw materials, but rather by a plating process or the like. Accordingly, their physical performance may be degraded, and it may be difficult to fabricate the entire probe pin in various shapes. Also, the application of alloy materials is limited.

Further, when probe pins are fabricated using a plate-shaped material, as described in Korean Patent No. 10-2292037, via a pressing or bending process, the loss rate of the probe pins after processing is high.

### PRIOR ART DOCUMENT

Patent Document 1: Korean Patent No. 10-2164020 (published on October 13, 2020)

Patent Document 2: Korean Patent No. 10-2349333 (published on January 11, 2022)

Patent Document 3: Korean Patent No. 10-2292037 (published on August 23, 2021)

### DISCLOSURE OF THE INVENTION

### PROBLEMS TO BE SOLVED BY THE INVENTION

The present disclosure has been conceived to provide a probe pin for inspecting a semiconductor chip by contacting the semiconductor chip, wherein the probe pin can be formed into various shapes, exhibits excellent physical performance, and allows the application of alloy materials.

However, the problems to be solved by the present disclosure are not limited to the above-described problems. Although not described herein, other problems to be solved by the present disclosure can be clearly understood by a person with ordinary skill in the art from the following descriptions.

### MEANS FOR SOLVING THE PROBLEMS

An embodiment of the present disclosure provides a probe pin used in a semiconductor inspection apparatus for inspecting a semiconductor chip by receiving an electrical signal from a tester, and the probe pin includes: a connection part electrically connected to the tester’s side; a tension part having one end connected to the connection part and configured to be subjected to tension when the probe pin comes into contact with the semiconductor chip; and a contact part having one end connected to the other end of the tension part and the other end configured to come into contact with the semiconductor chip. Cross-sections of the connection part and the contact part have rectangular cross-sections with rounded corners, and the tension part extends in a longitudinal direction, is recessed in a width direction, and is curved in one direction or both directions.

The tension part may have a greater length than the connection part and the contact part.

The tension part may have a length corresponding to lengths of the connection part and the contact part.

The tension part may further include a through-hole formed to penetrate along a height direction.

One end and the other end of the tension part may be located at corresponding positions.

One end and the other end of the tension part may be arranged diagonally.

One end of the connection part and the other end of the contact part may be formed into any one of a crown shape, a blade shape, a flat shape, an N-shape, a round shape, and an NF-shape.

The connection part, the tension part, and the contact part may be made of an alloy material.

An outer circumferential surface of the tension part may be coated with an insulation coating.

The insulation coating may be composed of any one of parylene, acrylic, polyamide, and an organic compound.

Another embodiment of the present disclosure provides a method of fabricating a probe pin used in a semiconductor inspection apparatus for inspecting a semiconductor chip by receiving an electrical signal from a tester, and the method includes: a first process of drawing a member; a second process of shaping the drawn member to have a rectangular cross-section with rounded corners; and a third process of pressing a middle portion of the shaped member in one direction or both directions.

The method may further include a process of cutting the pressed middle portion to correspond to lengths of an upper portion and a lower portion of the member.

The method may further include a process of forming a through-hole in the pressed middle portion along a height direction.

In the third process, the pressing may be performed to position the upper portion and the lower portion of the member at corresponding positions.

In the third process, the pressing may be performed to arrange the upper portion and the lower portion of the member to be diagonally inclined.

The method may further include a process of shaping both ends of the pressed member to have any one of a crown shape, a blade shape, a flat shape, an N-shape, a round shape, and an NF-shape.

The member may be made of an alloy material.

The method may further include a process of applying an insulation coating to an outer circumferential surface of the middle portion of the member that has been pressed in one direction or both directions in the third process.

### EFFECTS OF THE INVENTION

A probe pin according to an embodiment of the present disclosure integrally includes a connection part, a tension part, and a contact part. Also, by forming the tension part into various shapes, the probe pin can maintain constant elastic behavior while exhibiting excellent physical performance upon contact with a semiconductor chip, and can support a fine pitch.

However, the effects of the present disclosure are not limited to the above-described effects. Although not described herein, other effects of the present disclosure can be clearly understood by a person with ordinary skill in the art from the following descriptions.

### BRIEF DESCRIPTION OF THE DRAWINGS

FIG. 1 is a perspective view illustrating a probe pin according to an embodiment of the present disclosure.

FIG. 2 is a perspective view illustrating a through-hole formed in the probe pin according to an embodiment of the present disclosure.

FIG. 3A is a perspective view illustrating a probe pin curved in one direction according to another embodiment of the present disclosure.

FIG. 3B is a perspective view illustrating a probe pin curved in both directions according to another embodiment of the present disclosure.

FIG. 4 is a perspective view illustrating the probe pin according to yet another embodiment of the present disclosure.

FIGS. 5 A to 5F illustrate the shapes of one end of a connection part and the other end of a contact part in the probe pin according to an embodiment of the present disclosure.

FIG. 6 illustrates a guide plate formed in a tester of the present disclosure.

FIG. 7 is a flowchart showing a method of fabricating the probe pin according to an embodiment of the present disclosure.

FIG. 8 is a flowchart showing a method of fabricating a probe pin according to another embodiment of the present disclosure.

### MODE FOR CARRYING OUT THE INVENTION

Hereinafter, embodiments will be described in detail with reference to the accompanying drawings so that the present disclosure may be readily implemented by a person with ordinary skill in the art. However, it is to be noted that the present disclosure is not limited to the embodiments but can be embodied in various other ways. In the drawings, parts irrelevant to the description are omitted for the simplicity of explanation, and like reference numerals denote like parts throughout the whole document.

Throughout the whole document, a certain part “including” a certain element signifies that the certain part may further include another element instead of excluding other elements unless particularly indicated otherwise. Also, throughout the whole document, the term “connected to” may be used to designate a connection or coupling of one element to another element and includes both an element being directly connected to another element, an element being connected to another element via another element, and an element being electronically connected to another element via another element. Throughout the whole document, the term “on” that is used to designate a position of one element with respect to another element includes both a case that the one element is adjacent to the other element and a case that any other element exists between these two elements. Further, the expression “a first”, “a second”, “the first”, or “the second” used in the present disclosure may modify various components regardless of the order and/or the importance, and is used only to distinguish one element from another element, but does not limit the corresponding elements. For example, a first direction and a second direction may indicate the same direction or may indicate different directions.

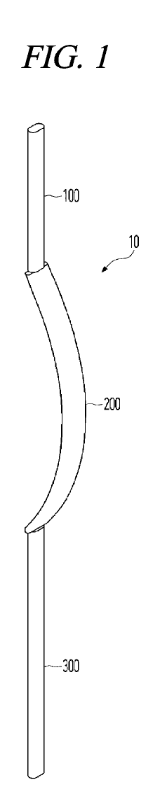

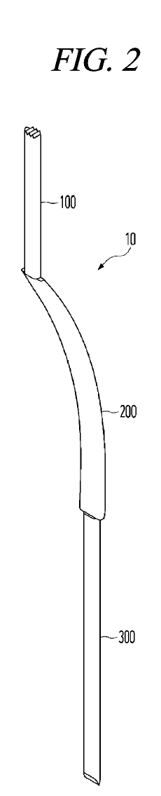

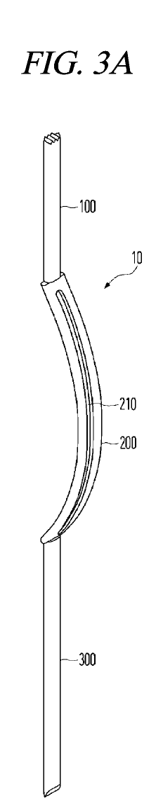

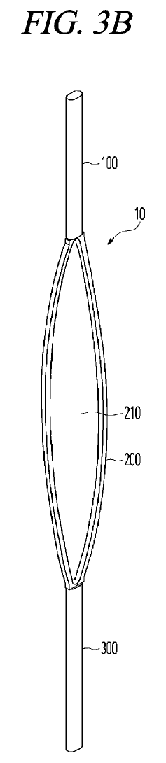

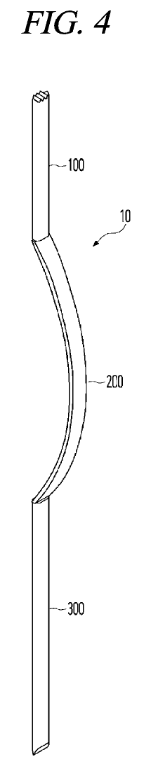

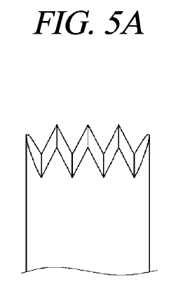

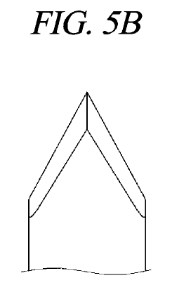

FIG. 1 is a perspective view illustrating a probe pin 10 according to an embodiment of the present disclosure, FIG. 2 is a perspective view illustrating a through-hole formed in the probe pin 10 according to an embodiment of the present disclosure, FIG. 3A is a perspective view illustrating a probe pin curved in one direction or both directions according to another embodiment of the present disclosure, FIG. 3B is a perspective view illustrating a probe pin curved in both directions according to another embodiment of the present disclosure, and FIG. 4 is a perspective view illustrating the probe pin 10 according to yet another embodiment of the present disclosure.

As shown in FIG. 1 to FIG. 4, the probe pin 10 may include a connection part 100, a tension part 200, and a contact part 300.

Herein, the probe pin 10 may contact a semiconductor chip to be inspected and be connected to a tester in order to form an electrical connection between the semiconductor chip and the tester.

The connection part 100 is electrically connected to the tester that applies an electrical signal, and may have a rectangular cross-section with rounded corners.

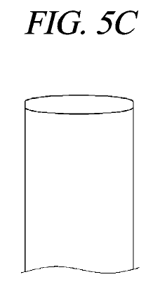

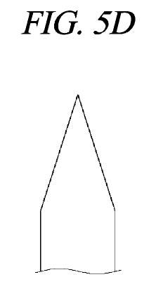

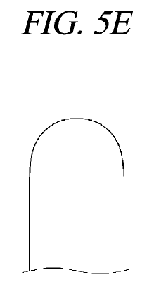

FIGS. 5 A to 5F illustrate the shapes of one end of the connection part 100 and the other end of the contact part 300 in the probe pin 10 according to an embodiment of the present disclosure.

One end of the connection part 100 may be formed into various shapes depending on the contact shape at the tester, the type of tester, and the like.

For example, as shown in FIGS. 5 A to 5F, one end of the connection part 100 may be formed into any one of a crown shape (FIG. 5A), a blade shape (FIG. 5B), a flat shape (FIG. 5C), an N-shape (FIG. 5D), a round shape (FIG. 5E), and an NF-shape (FIG. 5F).

As such, one end of the connection part 100 is formed into a shape most suitable for the contact shape at the tester and the type of tester, and thus it can be used with various testers. The tension part 200 is connected to the connection part 100, and tension may be applied when the probe pin 10 comes into contact with the semiconductor chip.

As shown in FIG. 1, the tension part 200 extends in a longitudinal direction, is recessed in a width direction, and may be curved in one direction or both directions.

Specifically, the tension part 200 extends in the longitudinal direction, and a width of the tension part 200 is recessed relative to a width of the connection part 100. Also, as the tension part 200 is curved in one direction, compressive stress generated when the probe pin 10 connected to the tester contacts the semiconductor chip occurs in the tension part 200, and the tension part 200 may be bent to one side or both sides.

By bending the tension part 200 in one direction, interference between adjacent probe pins 10 can be suppressed, thereby improving the inspection reliability for fine-pitch semiconductor chips.

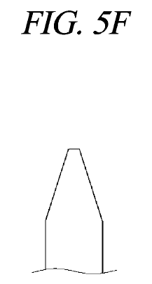

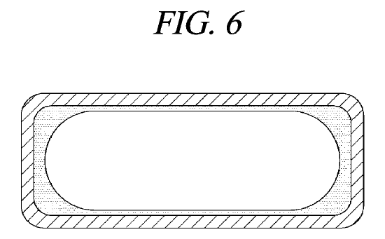

FIG. 6 illustrates a guide plate formed in a tester of the present disclosure.

The tension part 200 may have a greater length than the connection part 100 and the contact part 300. Accordingly, compressive stress generated when the probe pin 10 connected to the tester contacts the semiconductor chip is further generated in the tension part 200, thereby reducing the force applied to the connection part 100 and the contact part 300.

In this case, an insertion hole in the guide plate formed in the tester of the present disclosure may have a rectangular shape, as shown in FIG. 6.

Further, as shown in FIG. 4, the tension part 200 may have a length corresponding to lengths of the connection part 100 and the contact part 300.

The tension part 200 may further include a through-hole 210 formed to penetrate along a height direction.

As shown in FIG. 3A and FIG. 3B, since the tension part 200 further includes the through-hole 210 formed to penetrate along the height direction, compressive stress generated when the probe pin 10 connected to the tester contacts the semiconductor chip is further generated in the tension part 200, thereby reducing the force applied to the connection part 100 and the contact part 300.

Referring to FIG. 1, FIG. 2, and FIG. 4, one end and the other end of the tension part 200 may be located at corresponding positions, or as shown in FIG. 3A and FIG. 3B, one end and the other end of the tension part 200 may be arranged diagonally.

Herein, during a pressing process in a method of fabricating the probe pin 10 according to an embodiment of the present disclosure to be described later, one end and the other end of the tension part 200 may be located at corresponding positions, or one end and the other end of the tension part 200 may be arranged diagonally, depending on the shape of a lower portion of a compression press or the position of a fixing part.

Meanwhile, an outer circumferential surface of the tension part 200 may be coated with an insulation coating.

The insulation coating may be composed of parylene, acrylic, polyimide, and an organic compound. However, the present disclosure is not limited thereto. For example, the insulation coating may be composed of an organic compound, such as urethane or polyester.

Since the outer circumferential surface of the tension part 200 is coated with an insulation coating, it is possible to suppress the occurrence of an electrical short when inspecting the semiconductor chip by receiving an electrical signal from the tester.

One end of the contact part 300 may be connected to the other end of the tension part 200 and the other end thereof may contact the semiconductor chip, and a cross-section of the contact part 300 may have an elongated hole shape.

For example, as shown in FIG. 1 to FIG. 6, the cross-section of the contact part may have a circular shape extending in the longitudinal direction so as to be inserted into the insertion hole in the guide plate.

Specifically, as shown in FIG. 1 to FIG. 6, the elongated hole shape refers to a shape formed by pressing a circular shape in a vertical direction, wherein opposing side portions may be curved outward, and the upper and lower portions may be straight.

The other end of the contact part 300 may be formed into various shapes depending on the contact shape at the semiconductor chip and the type of semiconductor chip.

For example, as shown in FIGS. 5 A to 5F, one end of the connection part 100 may be formed into any one of a crown shape (FIG. 5A), a blade shape (FIG. 5B), a flat shape (FIG. 5C), an N-shape (FIG. 5D), a round shape (FIG. 5E), and an NF-shape (FIG. 5F).

As such, the other end of the contact part 300 is formed into a shape most suitable for the contact shape at the semiconductor chip and the type of semiconductor chip, and thus it can be used with various testers.

The connection part 100, the tension part 200, and the contact part 300 may be made of an alloy material.

A conventional probe pin is fabricated via a MEMS process by depositing materials layer by layer, which results in unstable physical properties and necessitates a separate plating process. In contrast, since the connection part 100, the tension part 200, and the contact part 300 are made of an alloy material, a separate plating process is unnecessary and layers are not formed, which can provide stable physical properties. However, the present disclosure is not limited thereto. For example, a separate plating process may be performed to improve electrical characteristics.

For example, the alloy material may be a single metal or a composite alloy composed of any one of a vanadium alloy, a rhodium alloy, and a palladium alloy.

These components are made of any one of a vanadium alloy, a rhodium alloy, a palladium alloy, or a composite alloy, and, thus, the probe pin can have superior electrical and mechanical properties compared to a probe pin fabricated via a MEMS process.

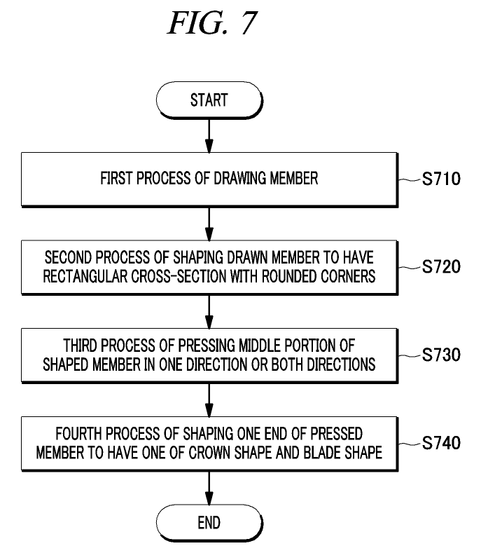

FIG. 7 is a flowchart showing a method of fabricating the probe pin 10 according to an embodiment of the present disclosure.

As shown in FIG. 7, the method of fabricating the probe pin 10 according to an embodiment of the present disclosure may include a first process (S710) of drawing a member, a second process (S720) of shaping a cross-section of the drawn member into an elongated hole-shape, and a third process (S730) of pressing a middle portion of the shaped member in one direction.

The member drawn in the first process (S710) may have a cylindrical shape with a circular cross-section and extend in the longitudinal direction.

As shown in FIG. 7, in the second process (S720), a cross-section of the drawn member may be shaped into an elongated hole shape. The shaping method is not limited to pressing the member in four directions or polishing the outer circumferential surface of the drawn member into a rectangular prism.

In the third process (S730), a middle portion of the shaped member may be pressed in one direction.

Meanwhile, the method may further include a process of cutting the pressed middle portion to correspond to lengths of an upper portion and a lower portion of the member, as shown in FIG. 4.

Further, as shown in FIG. 2, the method may further include a process of forming a through-hole in the pressed middle portion along a height direction.

Furthermore, as shown in FIG. 1 to FIG. 4, in the third process, the pressing may be performed to position the upper portion and the lower portion of the member at corresponding positions or to arrange the upper portion and the lower portion of the member to be diagonally inclined.

For example, depending on the shape of the lower portion of the compression press or the position of the fixing part, the pressing may be performed to position the upper portion and the lower portion of the member at corresponding positions or to arrange the upper portion and the lower portion of the member to be diagonally inclined.

Furthermore, as shown in FIG S . 5 A to 5F, the method may further include a fourth process (S740) of shaping both ends of the pressed member to have one of a crown shape (FIG. 5A) and a blade shape (FIG. 5B).

Accordingly, since both ends of the pressed member are formed into various shapes, they can be processed for use according to the types of semiconductor chips and testers.

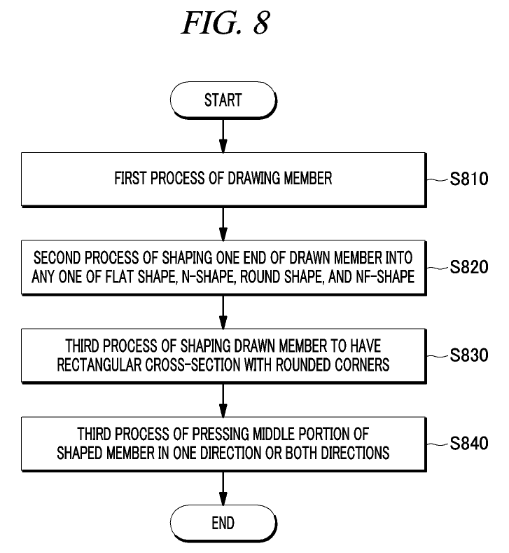

FIG. 8 is a flowchart showing a method of fabricating a probe pin according to another embodiment of the present disclosure.

As shown in FIG. 8, the method of fabricating the probe pin 10 according to another embodiment of the present disclosure may include a first process (S810) of drawing a member, a second process (S820) of shaping one end of the drawn member into any one of a flat shape (FIG. 8C), an NF-shape (FIG. 8D), and a round shape (FIG. 8E), a third process (S830) of shaping the shaped member to have a rectangular cross-section with rounded corners, and a fourth process (S840) of pressing a middle portion of the shaped member in one direction or both directions.

One end of the connection part 100 may be formed into any one of a crown shape (FIG. 8A), a blade shape (FIG. 8B), a flat shape (FIG. 8C), an NF-shape (FIG. 8D), and a round shape (FIG. 8E). In an embodiment, when one end of the connection part 100 has a crown shape (FIG. 8A) or a blade shape (FIG. 8B), the probe pin may be fabricated by the method of fabricating a probe pin according to the embodiment shown in FIG. 7. In another embodiment, when one end of the connection part 100 has a flat shape (FIG. 8C), an NF-shape (FIG. 8D), or a round shape (FIG. 8E), the probe pin may be fabricated by the method of fabricating a probe pin according to the other embodiment shown in FIG. 8.

The member used in fabricating the probe pin 10 may be made of a raw material or an alloy material.

Since the member is made of an alloy material, a separate plating process is unnecessary and layers are not formed, which can provide stable physical properties.

However, the present disclosure is not limited thereto. For example, a separate plating process may be performed to improve electrical characteristics.

Furthermore, the alloy material may include any one of a vanadium alloy, a rhodium alloy, a palladium alloy, or a composite alloy.

The member is made of vanadium, rhodium, palladium, and alloys thereof, and, thus, the probe pin can have superior electrical and mechanical properties compared to the probe pin 10 fabricated via a MEMS process.

As described above, the probe pin 10 according to the present disclosure integrally includes the connection part 100, the tension part 200, and the contact part 300, and by forming the tension part 200 into various shapes, the probe pin 10 can maintain constant elastic behavior while exhibiting excellent physical performance upon contact with a semiconductor chip, and can support a fine pitch.

Further, the tension part 200 has a greater length than the connection part 100 and the contact part 300, or the tension part 200 further includes the through-hole 210 formed to penetrate along the height direction. Thus, compressive stress generated when the probe pin 10 connected to the tester contacts the semiconductor chip is dispersed to the tension part 200, thereby reducing the force applied to the connection part 100 and the contact part 300.

The above description of the present disclosure is provided for the purpose of illustration, and it would be understood by a person with ordinary skill in the art that various changes and modifications may be made without changing technical conception and essential features of the present disclosure. Thus, it is clear that the above-described embodiments are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

### EXPLANATION OF CODES

10: Probe pin

100: Connection part

200: Tension part

210: Through-hole

300: Contact part

We claim:

1. A probe pin that is used in a semiconductor inspection apparatus for inspecting a semiconductor chip by receiving an electrical signal from a tester, the probe pin comprising: a connection part electrically connected to the tester; a tension part having one end connected to the connection part and configured to be subjected to tension when the probe pin comes into contact with the semiconductor chip; and a contact part having one end connected to the other end of the tension part and the other end configured to come into contact with the semiconductor chip, wherein cross-sections of the connection part and the contact part have elongated hole shapes, and the tension part extends in a longitudinal direction, is recessed in a width direction, and is curved in one direction or both directions.

2. The probe pin of claim 1, wherein the tension part has a greater length than the connection part and the contact part.

3. The probe pin of claim 1, wherein the tension part has a length corresponding to lengths of the connection part and the contact part.

4. The probe pin of claim 1, wherein the tension part further includes a through-hole formed to penetrate along a height direction.

5. The probe pin of claim 1, wherein one end and the other end of the tension part are located at corresponding positions.

6. The probe pin of claim 1, wherein one end and the other end of the tension part are arranged diagonally.

7. The probe pin of claim 1, wherein one end of the connection part and the other end of the contact part are formed into any one of a crown shape, a blade shape, a flat shape, an N-shape, a round shape, and an NF-shape.

8. The probe pin of claim 1, wherein the connection part, the tension part, and the contact part are made of an alloy material.

9. The probe pin of claim 1, wherein an outer circumferential surface of the tension part is coated with an insulation coating.

10. The probe pin of claim 9, wherein the insulation coating is composed of any one of parylene, acrylic, polyamide, and an organic compound.

11. A method of manufacturing a probe pin used in a semiconductor inspection apparatus for inspecting a semiconductor chip by receiving an electrical signal from a tester, comprising: a first process of drawing a member; a second process of shaping a cross-section of the drawn member into an elongated hole shape; anda third process of pressing a middle portion of the shaped member in one direction or both directions.

12. The method of claim 11, further comprising:
a process of cutting the pressed middle portion to correspond to lengths of an upper portion and a lower portion of the member.

13. The method of claim 11, further comprising: a process of forming a through-hole in the pressed middle portion along a height direction.

14. The method of claim 11, wherein in the third process, the pressing is performed to position an upper portion and a lower portion of the member at corresponding positions.

15. The method of claim 11, wherein in the third process, the pressing is performed to arrange the upper portion and the lower portion of the member to be diagonally inclined.

16. The method of claim 11, further comprising: a fourth process of shaping both ends of the pressed member to have one of a crown shape and a blade shape.

17. The method of claim 11, wherein the member is made of an alloy material.

18. The method of claim 11, further comprising: a process of applying insulation coating to an outer circumferential surface of the middle portion of the member that has been pressed in one direction or both directions in the third process.

19. The method of claim 18, wherein the insulation coating is composed of any one of parylene, acrylic, polyamide, and an organic compound.
